(19) United States
(12) Patent Application Publication
(10) Pub. No.: US 2025/0349375 A1
(43) Pub. Date: Nov. 13, 2025

(54) NON-VOLATILE MEMORY DEVICE, STORAGE DEVICE INCLUDING NON-VOLATILE MEMORY DEVICE, AND METHOD OF OPERATING STORAGE DEVICE

(71) Applicant: SAMSUNG ELECTRONICS CO., LTD., Suwon-si (KR)

(72) Inventors: Seoyeon Choi, Suwon-si (KR); Jae-Duk Yu, Suwon-si (KR); Sang Soo Park, Suwon-si (KR); Jonghoon Park, Suwon-si (KR)

(21) Appl. No.: 19/170,675

(22) Filed: Apr. 4, 2025

(30) Foreign Application Priority Data
May 10, 2024 (KR) 10-2024-0062204

(51) Int. Cl. G11C 16/34; G11C 16/08

(52) U.S. Cl. CPC G11C 16/3495; G11C 16/08; G11C 16/3418

(57) ABSTRACT

An example storage controller includes a host interface, a flash conversion layer, and a flash interface. The host interface receives a read request or a program request from a host device. The flash conversion layer collects deterioration information on a non-volatile memory device and log the deterioration information in a unit of a sub-block, determines a selected sub-block and an adjacent sub-block adjacent to the selected sub-block based on the read request or the program request, and generates a command that adjusts a core of the adjacent sub-block based on the deterioration information. The flash interface transfers the command to the non-volatile memory device.

### CROSS-REFERENCE TO RELATED APPLICATION

This application claims priority to and the benefit of Korean Patent Application No. 10-2024-0062204 filed at the Korean Intellectual Property Office on May 10, 2024, the entire contents of which are incorporated herein by reference.

### BACKGROUND

A memory device is used to store data, and is divided into a volatile memory device and a non-volatile memory device. A flash memory device that is an example of the non-volatile memory device may be used in a mobile phone, a digital camera, a personal digital assistant (PDA), a mobile computer device, a fixed computer device, or another device.

To improve storage capacity and integration of the non-volatile memory device, the non-volatile memory device (for example, a 3D NAND flash memory) that stacks memory cells in a three-dimensional structure is being researched.

Accordingly, the non-volatile memory device is being developed as a capacity of one memory block increases. However, as the capacity of the memory block becomes larger, it is not easy to provide performance suitable for the increased capacity with an existing block-by-block control technology or algorithm.

### SUMMARY

The present disclosure relates to a non-volatile memory device that improves a reliability problem caused by a disturb phenomenon due to an operation of an adjacent sub-block, a storage device including the non-volatile memory device, and a method of operating the storage device.

The present disclosure relates to a non-volatile memory device that improves performance by reducing the number of read reclaim operations, a storage device including the non-volatile memory device, and a method of operating the storage device.

In general, according to some aspects, a storage controller includes: a host interface that receives a read request or a program request from a host device; a flash conversion layer that collects deterioration information on a non-volatile memory device in a unit of a sub-block, determines a selected sub-block and an adjacent sub-block adjacent to the selected sub-block based on the read request or the program request, and generates a command adjusting a core of the adjacent sub-block based on the deterioration information; and a flash interface that transfers the command adjusting the core of the adjacent sub-block to the non-volatile memory device.

In general, according to some aspects, a storage device includes: a storage controller that determines a selected sub-block and an adjacent sub-block adjacent to the selected sub-block among a plurality of sub-blocks based on a read request or a program request from a host device and generates a command adjusting a core of the adjacent sub-block if a disturb generated in the adjacent sub-block exceeds a first reference value; and a non-volatile memory device that includes the plurality of sub-blocks and adjusts a size of a pass voltage applied to a word line included in the adjacent sub-block among the plurality of sub-blocks based on the command and an address of the adjacent sub-block.

In general, according to some aspects, a method of operating the storage device includes: determining a selected sub-block that is a target of a read operation or a program operation among a plurality of sub-blocks distinguished from each other through a plurality of word lines; determining whether deterioration information of an adjacent sub-block adjacent to the selected sub-block is greater than or equal to a first reference value; and adjusting a core of the adjacent sub-block if the deterioration information of the adjacent sub-block is greater than or equal to the first reference value.

### BRIEF DESCRIPTION OF THE DRAWINGS

FIG. 1 is a block diagram showing an example of a storage device and an example of a storage system including the storage device.

FIG. 2 is a block diagram showing an example of a storage device.

FIG. 3 is a block diagram showing an example of a storage controller.

FIG. 4 is a block diagram showing an example of a non-volatile memory device.

FIG. 5 is a view for describing an example of a 3-dimensional structure of a memory cell array of FIG. 4.

FIG. 6 is an example perspective view showing the memory cell array of FIG. 4.

FIG. 7 is an example plan view showing a memory cell array of FIG. 5.

FIG. 8 is a view showing an example of a cross-section of a channel hole.

FIG. 9 is a view showing an example of a cross-section of a channel hole.

FIG. 10 is a flowchart for describing an example of a method of operating the storage device.

FIG. 11 is a flowchart for describing an example of a method of operating the storage device.

FIG. 12 is a view showing an example of a copyback process for an adjacent sub-block in which a read disturb count exceeds a deterioration threshold value.

FIG. 13 is a view showing an example of a program wearout count gradually increasing in an adjacent sub-block.

FIG. 14 is a view showing an example of a voltage applied to a memory cell included in each of sub-blocks of FIGS. 11 to 13.

FIG. 15 is a flowchart for describing an example of a method of operating the storage device.

FIG. 16 is a view showing an example of a program process in which an electron is filled in a floating gate included in a memory cell.

FIG. 17 is a view showing an example of an erase process in which an electron falls into a floating gate within a non-volatile memory device.

FIG. 18 is a view showing an example of a program/erase cycle count corresponding to each sub-block.

FIG. 19 is a view for describing an example of a threshold voltage for the sub-block of FIG. 18.

FIG. 20 is a view showing an example of a voltage applied to a memory cell included in each sub-block of FIG. 18.

FIG. 21 is a flowchart for describing an example of a method of operating the storage device.

FIG. 22 is a view showing an example of a retry count corresponding to each sub-block.

FIG. 23 is a view showing an example of a voltage applied to a memory cell included in each sub-block of FIG. 22.

FIG. 24 is a block diagram showing an example of a data storage device including a non-volatile memory device.

FIG. 25 is a block diagram showing an example of a computer system including a non-volatile memory device.

### DETAILED DESCRIPTION

Implementations of the present disclosure will be described more fully hereinafter with reference to the accompanying drawings so that those skilled in the art may easily implement the implementations. The present disclosure may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals. In a flowchart described with reference to the drawings, an order of operations may be changed, several operations may be merged, a certain operation may be divided, and a specific operation may not be performed.

In addition, a singular form may be intended to include a plural form as well, unless an explicit expression such as “one” or “single” is used. Terms including ordinal numbers such as first, second, and the like will be used only to describe various constituent elements, and are not to be interpreted as limiting the constituent elements. The terms may be used for a purpose of distinguishing one constituent element from other constituent elements.

Hereinafter, the present disclosure will be described in more detail through an example. The example is provided only for exemplifying of the present disclosure, and the scope of rights protection of the present disclosure is not limited by the example.

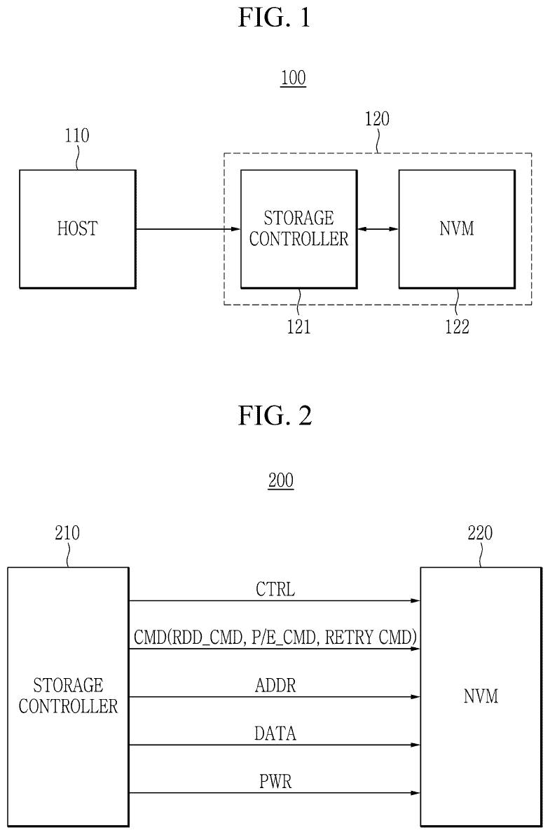

FIG. 1 is a block diagram showing an example of a storage device and an example of a storage system including the storage device.

Referring to FIG. 1, the storage system 100 may be a mobile system such as a mobile phone, a smart phone, a tablet personal computer (PC), a wearable device, a healthcare device, or an Internet of Things (IoT) device. In some implementations, the storage system 100 may be a computing device such as a personal computer, a laptop computer, a server, or a media player, or a system such as an automotive device (e.g., a navigation device).

The storage system 100 may include a host device 110 and the storage device 120. The host device 110 may store data in the storage device 120, or may read data stored in the storage device 120.

The storage device 120 may include a storage controller 121 and a non-volatile memory device 122. The storage controller 121 may control overall operation of the storage device 120. The storage controller 121 may receive a read request or a program request from the host device 110. The non-volatile memory device 122 may be a storage medium configured to store data or output stored data according to a request from the host device 110. As an example, the non-volatile memory device 122 may include at least one of a solid-state drive (SSD), an embedded memory, and a detachable external memory. If the non-volatile memory device 122 is the SSD, the non-volatile memory device 122 may be a device that conforms to a standard such as non-volatile memory express (NVMe), SATA, SAS, or the like. If the non-volatile memory device 122 is the embedded memory or the external memory, the non-volatile memory device 122 may be a device that conforms to a standard such as a universal flash storage (UFS), an embedded multi-media card (eMMC), a secure digital (SD) card, or the like, and the protocol is not limited thereto.

FIG. 2 is a block diagram showing an example of a storage device.

Referring to FIG. 2, the storage device 200 and a storage controller 210 and a non-volatile memory device 220 included in the storage device 200 may correspond to the storage device 120 and the storage controller 121 and the non-volatile memory device 122 included in the storage device 120 of FIG. 1, respectively.

The non-volatile memory device 220 may receive a command CMD, an address (ADDR), data (DATA), and a control signal (CTRL) from the storage controller 210 through a system bus. Additionally, the non-volatile memory device 220 may receive power (PWR) from the storage controller 210. The non-volatile memory device 220 may perform an erase operation, a program operation, a read operation, or the like based on the control signal CTRL received from the storage controller 210.

The storage controller 210 may collect and log deterioration information on the non-volatile memory device 220 in a unit of a sub-block. The deterioration information may include a program/erase cycle, a read disturb count, an erase count, a program wearout count, a wear level count, a retry count, an elapse time, an operation temperature, or the like. The deterioration information on the non-volatile memory device 220 may include cost information generated when a wear level between sub-blocks is performed and performance degradation information of the storage device 120 of FIG. 1 caused by read reclaim.

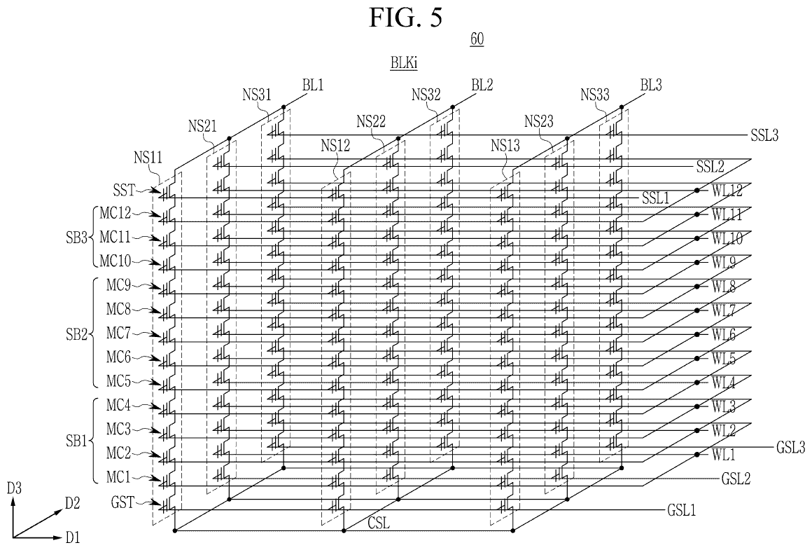

The storage controller 210 may manage the non-volatile memory device 220 as a small plurality of sub-blocks divided by a word line within one laminate. In the present disclosure, a detailed description of the sub-block will be described later with reference to FIGS. 5 to 9.

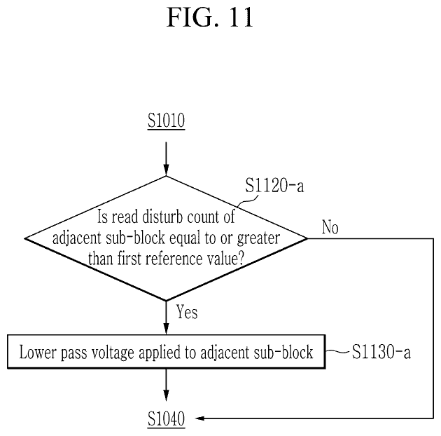

The storage controller 210 may monitor the sub-block by logging the deterioration information in a unit of a sub-block of the non-volatile memory device 220. The storage controller 210 may provide a read disturb command RDD_CMD, a program/erase cycle command P/E_CMD, or a retry command RETRY_CMD to the non-volatile memory device 220 as examples of a logged deterioration information. The read disturb command RDD_CMD may include a command for lowering a pass voltage applied to the sub-block in order to prevent deterioration due to a read disturb generated in the sub-block. The program/erase cycle command P/E_CMD may include a command for increasing a pass voltage applied to the sub-block to prevent deterioration due to a program/erase cycle generated in the sub-block. The retry command RETRY_CMD may include a command for changing a memory cell type of the sub-block that is a program target to prevent deterioration due to a retry occurring in the sub-block. A content thereof will be described with reference to FIGS. 11, 15, and 21.

The non-volatile memory device 220 may receive the read disturb command RDD_CMD, the program/erase cycle command P/E_CMD, or the retry command RETRY_CMD from the storage controller 210. The non-volatile memory device 220 may perform an operation of adjusting a core for the sub-block according to provision of the read disturb command RDD_CMD, the program/erase cycle command P/E_CMD, and the retry command RETRY_CMD. Details of the operation of adjusting the core of the sub-block will be described with reference to FIGS. 11, 15, and 21.

The non-volatile memory device 220 may adjust an operation condition such as an erase operation, a program operation, a read operation, or the like for a target sub-block according to movement of a distribution of a threshold voltage for a memory cell within the sub-block changed by a disturb.

Each of the storage controller 210 and the non-volatile memory device 220 may be provided as one chip, one package, one module, or the like. Alternatively, the storage controller 210 and the non-volatile memory device 220 may be mounted based on various packages to be provided as a storage device such as a memory card.

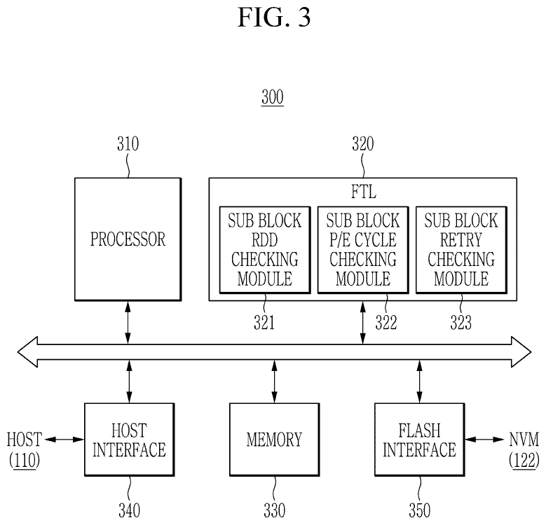

FIG. 3 is a block diagram showing an example of the storage controller.

Referring to FIG. 3, the storage controller 300 may include a processor 310, a flash conversion layer 320, a memory 330, a host interface 340, and a flash interface 350. The storage controller 300 may correspond to the storage controller 210 of FIG. 2.

The processor 310 may control the overall operation of the storage controller 300. The memory 330 may operate as a buffer memory, a cache memory, and an operation memory for the processor 310. Depending on the implementation, the memory 330 may include a DRAM, an SRAM, or the like, but the present disclosure is not limited thereto.

The flash conversion layer 320 (hereinafter referred to as “FTL”) may provide an interface between the host 110 and the non-volatile memory device 122 of FIG. 1 so that the non-volatile memory device 122 is efficiently used. According to some implementations, the FTL 320 may be a memory management module, and may perform an address mapping operation, a garbage collection operation, a wear leveling operation, a read reclaim operation, a log operation for the deterioration information in a sub-block unit, or the like.

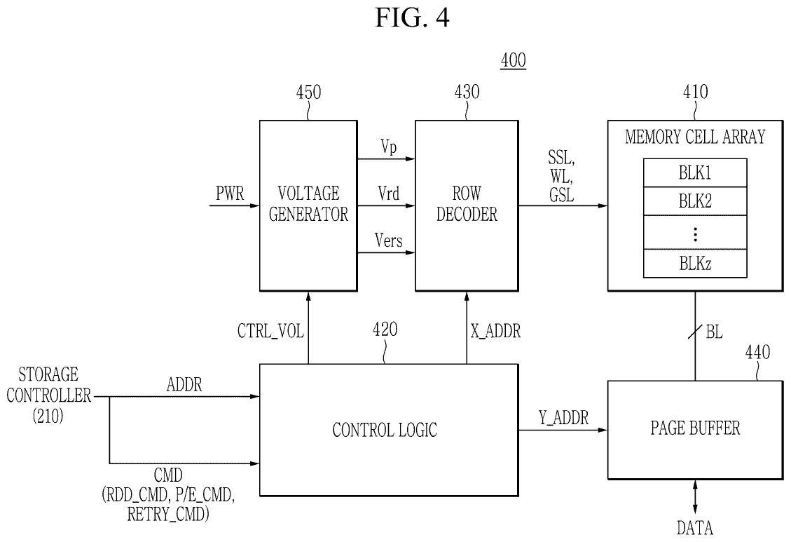

THE FTL 320 may collect the deterioration information on the non-volatile memory device in a unit of a sub-block. The FTL 320 may determine a selected sub-block and an adjacent sub-block adjacent to the selected sub-block based on the read request or the program request of the host device 110, and may generate a command for adjusting a core of the adjacent sub-block based on the collected deterioration information. In this case, the selected sub-block and the adjacent sub-block may be included in the same hole block, and the selected sub-block may refer to a memory block that is read or programmed. Details thereof will be described with reference to FIGS. 4, 8, and 9.

THE FTL 320 may include a sub-block read disturb checking module SUB BLOCK RDD CHECKING MODULE (hereinafter referred to as “RDM 321”) generating a first command RDD_CMD for adjusting a pass voltage applied to the adjacent sub-block based on the read disturb count included in the deterioration information, a sub-block program/erase cycle checking module SUB BLOCK P/E CYCLE CHECKING MODULE (hereinafter referred to as “PEM 322”) generating a second command P/E_CMD for adjusting a pass voltage applied to the adjacent sub-block based on the program/erase cycle count included in the deterioration information, and a sub-block retry checking module SUB BLOCK RETRY CHECKING MODULE (hereinafter referred to as “RTM 323”) generating a third command RETRY_CMD for adjusting a pass voltage applied to the adjacent sub-block based on the retry count included in the deterioration information. THE RDM 321, the PEM 322, and the RTM 323 may monitor a disturb situation of the sub-block by logging an operation or the like for the sub-block.

THE RDM 321, the PEM 322, and the RTM 323 may determine the disturb situation for the sub-block based on the log information, and the storage controller 300 may provide the read disturb command RDD_CMD, the program/erase cycle command P/E_CMD, and the retry command RETRY_CMD to the non-volatile memory device 122 according to the determination.

Specifically, if the number of read disturbs occurring in the adjacent sub-block is determined to be greater than or equal to a first reference value, the RDM 321 may generate the first command RDD_CMD that lowers the pass voltage applied to the adjacent sub-block. If the number of program/erase cycles occurring in the adjacent sub-block is determined to be greater than or equal to the first reference value, the PEM 322 may generate the second command P/E_CMD that increases the pass voltage applied to the adjacent sub-block. If the number of retries occurring in the adjacent sub-block is determined to be greater than or equal to the first reference value, the RTM 323 may generate the third command RETRY_CMD that changes the memory cell type included in the selected sub-block. In some implementations, if the number of retries occurring in the adjacent sub-block is determined to be greater than or equal to the first reference value, the RTM 323 may generate the third command RETRY_CMD changing memory cell types of all sub-blocks within a hole block including the selected sub-block. In this case, the third command may be a command for changing the memory cell type to a single level cell (SLC) type.

According to some implementations, the FTL 320 may be a dedicated circuit and may be provided in a hardware form, but the present disclosure is not limited thereto. According to some implementations, the FTL 320 may be provided in a software form, and if the FTL 320 is provided in the software form, the FTL 320 may be loaded into the memory 330 to be operated by the processor 310.

The storage controller 300 may receive the read request or the program request from the host device 110 through the host interface 340. The storage controller 300 may transfer the command for adjusting the core of the adjacent sub-block to the non-volatile memory device 122 through the flash interface 350. The host interface 340 and the flash interface 350 may include various interfaces such as a Universal Serial Bus (USB), a multimedia card (MMC), a peripheral component interconnection (PCI), a PCI-express (PCI-E), an Advanced Technology Attachment (ATA), a Serial-ATA, a Parallel-ATA, a small computer small interface (SCSI), an enhanced small disk interface (ESDI), Integrated Drive Electronics (IDE), a mobile industry processor interface (MIPI), an NVMe, and the like.

Memory cells included in the non-volatile memory device 122 of FIG. 1 may have a physical characteristic in which a distribution of a threshold voltage changes due to factors such as a program elapsed time, a temperature, a disturb due to an operation of the adjacent sub-block, and the like. That is, an error may occur in data stored in the non-volatile memory device 122 due to the above-described factors.

Although not shown in the drawings, the storage controller 300 may use various error correction techniques to correct the error, and for example, the storage controller 300 may include an error correction code (ECC) engine. However, there may be a case where an error correction is not possible due to the ECC engine. In this case, the FTL 320 may perform the read reclaim operation for overcoming the error correction impossibility. The read reclaim operation may be performed based on the deterioration information.

The read reclaim operation may be a copyback operation of moving data stored in the memory block or the sub-block before an uncorrectable error occurs among data stored in the memory block or the sub-block to another memory block or another sub-block. According to some implementations, the FTL 320 may provide the command CMD to the non-volatile memory device 122 so that the read reclaim operation is performed on the sub-block before the uncorrectable error occurs in the sub-block.

FIG. 4 is a block diagram showing an example of a non-volatile memory device.

Referring to FIG. 4, the non-volatile memory device 400 may include a memory cell array 410, control logic 420, a row decoder 430, a page buffer circuit 440, and a voltage generator 450. The non-volatile memory device 400 may correspond to the non-volatile memory device 220 of FIG. 2.

Although not shown in FIG. 4, according to some implementations, the non-volatile memory device 400 may further include a memory interface circuit, and may further include a column logic, a pre-decoder, a temperature sensor, a command decoder, an address decoder, or the like.

The memory cell array 410 may be connected to the page buffer circuit 440 through a plurality of bit lines BL, and may be connected to the row decoder 430 through a plurality of word lines WL, a plurality of string selection lines SSL, a plurality of ground selection lines GSL, and the like.

The memory cell array 410 may include a plurality of memory blocks BLK1-BLKz (where z is an integer equal to or greater than 3). Each of the plurality of memory blocks BLK1-BLKz may include a plurality of sub-blocks. Each of the plurality of sub-blocks may include a plurality of pages, and each of the plurality of pages may include a plurality of memory cells.

The number of pages included in each of the plurality of sub-blocks may be different, and accordingly, the number of memory cells included in each of the plurality of sub-blocks may also be different. Places of use for the plurality of sub-blocks may be different. For example, the sub-block with a large number of memory cells may be used for a process with a large amount of computation, and the sub-block with a small number of memory cells may be used for a process with a small amount of computation.

According to some implementations, the plurality of memory blocks BLK1-BLKz may be a single level cell block including a single level cell (SLC) storing 1-bit data, a multi-level cell block including a multi-level cell (MLC) storing at least 2-bit data, a triple level cell block including a triple level cell (TLC), or a quad level cell block including a quad level cell (QLC).

Referring to FIG. 4, the control logic 420 may receive the command CMD and the address ADDR from the storage controller 210 of FIG. 2, and may control an erase operation, a program operation, and a read operation of the non-volatile memory device 400 based on the command CMD and the address ADDR.

The control logic 420 may receive the read disturb command RDD_CMD, the retry command RETRY_CMD, or the program/erase cycle command P/E_CMD from the storage controller 210.

The control logic 420 may generate a voltage control signal CTRL_VOL based on the command CMD received from the storage controller 210. The control logic 420 may provide the voltage control signal CTRL_VOL that changes the pass voltage applied to the word line included in the adjacent sub-block to the voltage generator 450.

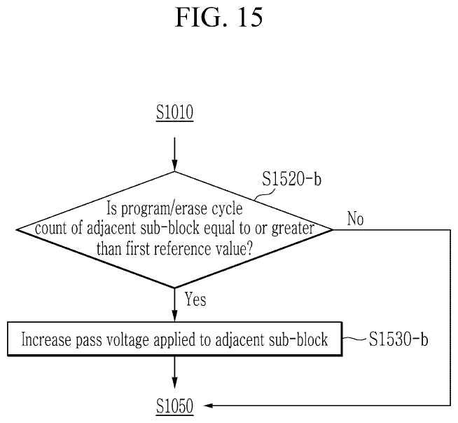

For example, the control logic 420 may generate the voltage control signal CTRL_VOL for lowering the pass voltage applied to the word line included in the sub-block based on the command RDD_CMD received from the storage controller 210 to provide the voltage control signal CTRL_VOL to the voltage generator 450. The control logic 420 may generate the voltage control signal CTRL_VOL for increasing the pass voltage applied to the word line included in the sub-block based on the command P/E_CMD received from the storage controller 210 to provide the voltage control signal CTRL_VOL to the voltage generator 450. The voltage generator 450 may generate the pass voltage applied to the word line of each memory cell included in the adjacent sub-block based on the voltage control signal CTRL_VOL. Details thereof will be described with reference to FIG. 11 and FIG. 15.

The control logic 420 may generate a row address X_ADDR and a column address Y_ADDR based on the address ADDR received from the storage controller 210. The control logic 420 may provide the row address X_ADDR to the row decoder 430, and may provide the column address Y_ADDR to the page buffer circuit 440.

The row decoder 430 may be connected to the memory cell array 410 through the plurality of word lines WL, the plurality of string selection lines SSL, and the plurality of ground selection lines GSL. The row decoder 430 may select some word lines of the plurality of word lines WL in response to the row address X-ADDR received from the control logic 420.

The page buffer circuit 440 may be connected to the memory cell array 410 through the plurality of bit lines BL. The page buffer circuit 440 may select some bit lines of the plurality of bit lines BL in response to the column address Y_ADDR received from the control logic 420.

During the read operation, the page buffer circuit 440 may sense data DATA stored in the memory cell array 410 based on the column address Y_ADDR. During the program operation, the page buffer circuit 440 may input the data DATA to be stored in the memory cell array 410 based on the column address Y_ADDR. The page buffer circuit 440 may store the data DATA read from the memory cell array 410 or the data DATA to be written in the memory cell array 410.

The voltage generator 450 may generate a program voltage Vp, a read voltage Vrd, an erase voltage Vers, and a pass voltage Vpass required for an operation of the non-volatile memory device 400 based on the voltage control signal CTRL_VOL provided from the control logic 420. The program voltage Vp, the read voltage Vrd, the erase voltage Vers, and the pass voltage Vpass generated from the voltage generator 450 may be applied to the plurality of word lines WL through the row decoder 430.

FIG. 5 is a view for describing an example of a 3-dimensional structure of the memory cell array of FIG. 4.

The memory block BLKi shown in FIG. 5 may be one of the plurality of memory blocks BLK1-BLKz of FIG. 4, and may represent a 3-dimensional memory block formed in a 3-dimensional structure. A plurality of memory cell strings included in the memory block BLKi may be formed in a third direction D3.

The memory block BLKi may include a plurality of memory cell strings NS11-NS33 connected between bit lines BL1, BL2, and BL3 and a common source line CSL. Each of the plurality of memory cell strings NS11-NS33 may include a string selection transistor SST, a plurality of memory cells MC1, MC2, . . . , MC12, and a ground selection transistor GST.

The string selection transistor SST may be connected to string selection lines SSL1, SSL2, and SSL3 corresponding to the string selection transistor SST. The plurality of memory cells MC1, MC2, . . . , MC12 may be connected to a word line corresponding to each of the plurality of memory cells MC1, MC2, . . . , MC12 among a plurality of word lines WL1, WL2, . . . , WL12. The ground selection transistor GST may be connected to ground selection lines GSL1, GSL2, and GSL3 corresponding to the ground selection transistor GST. The string selection transistor SST may be connected to bit lines BL1, BL2, and BL3 corresponding to the string selection transistor SST, and the ground selection transistor GST may be connected to the common source line CSL. Word lines (e.g., WL1) having the same height with respect to an axis in the third direction D3 may be connected in common, and the ground selection lines GSL1, GSL2, and GSL3 and the string selection lines SSL1, SSL2, and SSL3 may be separated from each other.

One memory block BLKi exemplarily described above may include a plurality of sub-blocks SB1, SB2, and SB3. Each of the plurality of sub-blocks SB1, SB2, and SB3 may be divided into the plurality of word lines WL1, WL2, . . . , WL12. Each of the plurality of sub-blocks SB1, SB2, and SB3 may be a unit of the erase operation, and may be erased independently of other sub-blocks within the memory block BLKi.

The first sub-block SB1 may include memory cells connected to the first to fourth word lines WL1, WL2, WL3, and WL4 among memory cells included in the memory block BLKi. The second sub-block SB2 may include memory cells connected to the fifth to ninth word lines WL5, WL6, WL7, WL8, and WL9 among the memory cells included in the memory block BLKi. The third sub-block SB3 may include memory cells connected to the tenth to twelfth word lines WL10, WL11, and WL12 among the memory cells included in the memory block BLKi.

One or more sub-blocks SB1, SB2, and SB3 may be simultaneously selected and erased. In this case, the row decoder 430 of FIG. 4 may provide a bias for erasing memory cells in a unit of a sub-block SBi. While an erase operation for one sub-block is performed, adjacent sub-blocks within the same memory block may be floated.

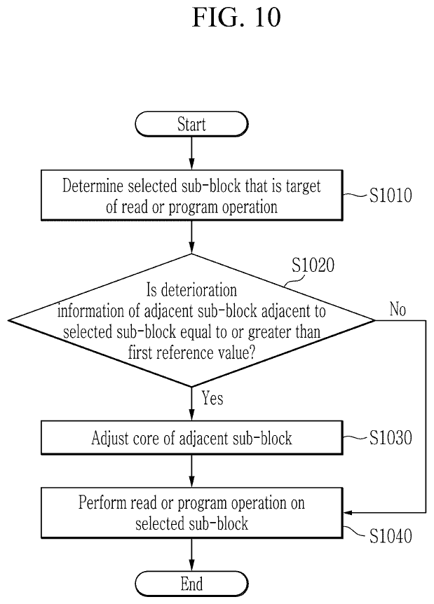

The control logic 420 of FIG. 4 may select the sub-block SB2 selected among the plurality of sub-blocks SB1, SB2, and SB3 and the adjacent sub-blocks SB1 and SB3 adjacent to the selected sub-block, and may adjust cores of the adjacent sub-blocks SB1 and SB3 based on the deterioration information of the selected sub-block SB2 and the adjacent sub-blocks SB1 and SB3. Details thereof will be described with reference to FIGS. 10 to 23.

The sub-block SBi may be any one of the plurality of sub-blocks SB1, SB2, and SB3, and hereinafter, a common description of the plurality of sub-blocks SB1, SB2, and SB3 may be replaced by a description of the sub-block SBi. Although FIG. 5 illustrates that the memory block BLKi includes three sub-blocks SB1, SB2, and SB3, the number of sub-blocks is an example for ease of description, and does not limit a technical idea of the present disclosure. Additionally, the number of memory cells included in each of the sub-blocks SB1, SB2, and SB3 is only an example, and does not limit the technical idea of the present disclosure.

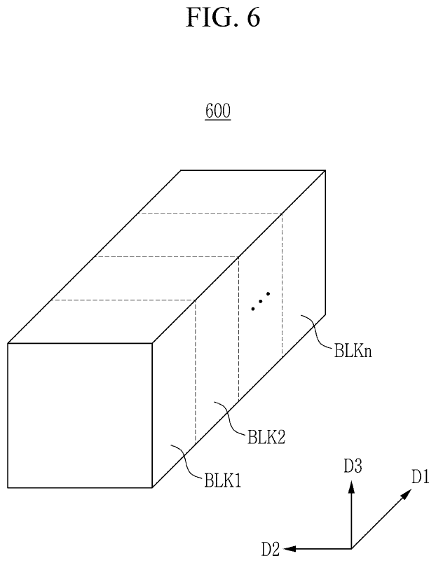

FIG. 6 is an example perspective view showing the memory cell array of FIG. 4.

Referring to FIG. 4 and FIG. 6, the memory cell array 410 may include the plurality of memory blocks BLK1-BLKz extending along first to third directions D1-D3. The plurality of memory blocks BLK1-BLKz may be selected by the row decoder 430. For example, the row decoder 430 may select a memory block BLK corresponding to the address ADDR among the plurality of memory blocks BLK1-BLKz. The row decoder 430 may select at least one sub-block SBi within the memory block BLK in response to the row address X_ADDR.

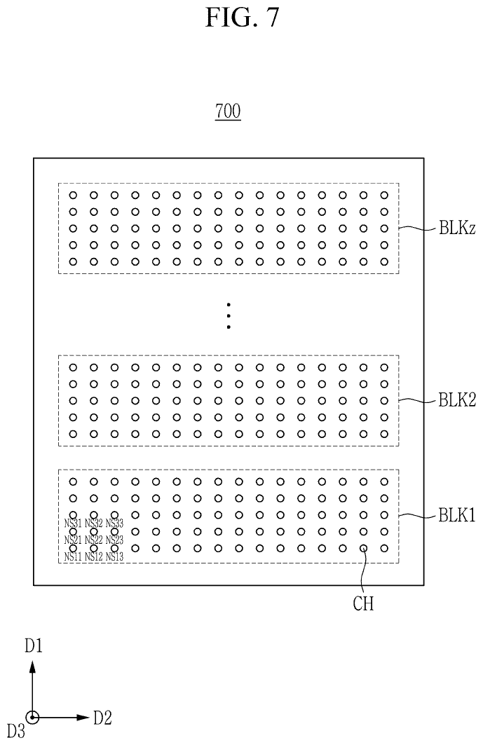

FIG. 7 is an example plan view showing a memory cell array of FIG. 5.

Referring to FIGS. 5 to 7, each of the plurality of memory blocks BLK1-BLKz may include a plurality of channel holes CH. According to some implementations, the plurality of channel holes CH may be disposed to be spaced apart from each other within the plurality of memory blocks BLK1-BLKz in the first direction D1 or the second direction D2.

Each channel hole CH may be extended in the third direction D3. Each channel hole CH may correspond to a memory cell string NS that is one of the plurality of memory cell strings NS11-NS33.

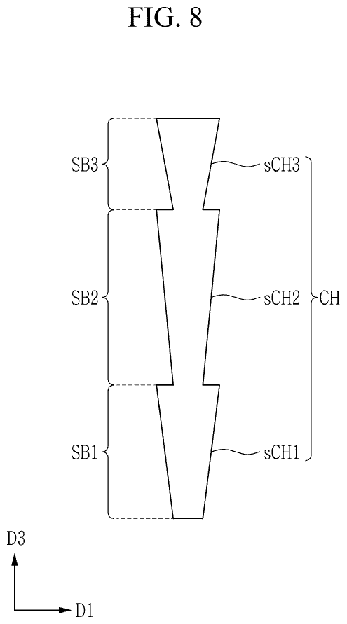

FIG. 8 is a view showing an example of a cross-section of the channel hole.

Referring to FIG. 8, the channel hole CH may include first to third sub-channel holes sCH1-sCH3 disposed along the third direction D3. According to some implementations, at least some of the first to third sub-channel holes sCH1-sCH3 may be disposed to overlap each other in the third direction D3.

Because each of the first to third sub-channel holes sCH1-sCH3 is formed by etching some regions of gate electrodes and insulation films, etching may not be performed well as a depth from an upper surface thereof to a lower surface thereof increases. Accordingly, diameters of the first to third sub-channel holes sCH1-sCH3 may decrease as they approach a lower surface thereof.

Although not shown in the drawings, a stopper layer may be disposed at a boundary between the sub-channel holes. For example, the stopper layer may be disposed at the boundary between the first and second sub-channel holes sCH1 and sCH2 and the boundary between the second and third sub-channel holes sCH2 and sCH3. The stopper layer may be a material layer disposed for stepwise formation of the sub-channel holes. A memory cell disposed at the stopper layer may operate as an intermediate switch transistor.

Each of the first to third sub-channel holes sCH1-sCH3 may correspond to the plurality of sub-blocks SB1, SB2, and SB3 in FIG. 5, respectively. In the first sub-channel hole sCH1, the memory cells connected to the first to fourth word lines WL1, WL2, WL3, and WL4 of FIG. 5 may be formed. In the second sub-channel hole sCH2, the memory cells connected to the fifth to ninth word lines WL5, WL6, WL7, WL8, and WL9 of FIG. 5 may be formed. In the third sub-channel hole sCH3, the memory cells connected to the tenth to twelfth word lines WL10, WL11, and WL12 of FIG. 5 may be formed.

Although FIG. 8 illustrates that the channel hole CH includes three sub-channel holes sCH1-sCH3, the number of the illustrated sub-channel holes is merely an example for ease of description, and the technical idea of the present disclosure is not limited thereto. Although it is described above that the three sub-blocks SB1, SB2, and SB3 respectively correspond to three sub-channel holes sCH1, sCH2, and sCH3, the three sub-blocks SB1, SB2, and SB3 may be used in various ways to correspond to the three sub-channel holes sCH1, sCH2, and sCH3. For example, SB3 may correspond to portions of sCH3 and sCH2, SB2 may correspond to the remaining portion of the sCH2, and SB1 may correspond to the sCH1.

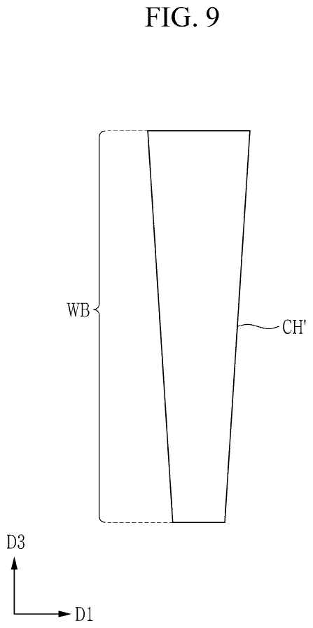

FIG. 9 is a view showing an example of a cross-section of a channel hole.

Referring to FIG. 9, the channel hole CH′ may correspond to the channel hole CH of FIG. 8. For ease of description, the channel hole CH′ of FIG. 9 is mainly described with reference to a difference between the channel hole CH′ of FIG. 9 and the channel hole CH of FIG. 8.

Referring to FIG. 5, FIG. 8, and FIG. 9, the channel hole CH′ may be formed through etching of one channel hole without stepwise formation of the plurality of sub-channel holes sCH1-sCH3. Accordingly, a diameter of the channel hole CH′ may become smaller as it approaches a lower surface thereof. According to some implementations, a stopper layer may not be disposed within the channel hole CH′.

The channel hole CH′ may correspond to a hole block WB including all of the plurality of sub-blocks SB1, SB2, and SB3 of FIG. 5. In the channel hole CH′, the memory cells connected to the first to twelfth word lines WL1 to WL12 of FIG. 5 may be formed.

FIG. 10 is a flowchart for describing an example of a method of operating the storage device.

Referring to FIGS. 1 to 10, in a step S1010, the storage controller 300 may receive a read request or a program request from the host device 110 of FIG. 1, and may determine a selected sub-block that is a target of a read or program operation.

In a step S1020, the flash conversion layer 320 may determine whether the deterioration information of the adjacent sub-block adjacent to the selected sub-block is greater than or equal to the first reference value. If the deterioration information of the adjacent sub-block is greater than or equal to the first reference value, in a step S1030, the flash conversion layer 320 may generate a command for adjusting a core of the adjacent sub-block.

In some implementations, the flash conversion layer 320 may generate a command adjusting a size of a gate voltage applied to the word line of the adjacent sub-block. In some implementations, the flash conversion layer 320 may generate a command adjusting an application time of the gate voltage applied to the word line of the adjacent sub-block. In some implementations, the flash conversion layer 320 may generate a command adjusting the number of bits stored by a cell included in each adjacent sub-block.

For example, a case in which the deterioration information is greater than or equal to the first reference value may include a case in which the read disturb count occurring in the adjacent sub-block is greater than or equal to 10 times, a case in which the program/erase cycle count occurring in the adjacent sub-block is greater than or equal to 100 k times, or a case in which the retry count occurring in the adjacent sub-block is greater than or equal to 10 times. However, this is only an example, and the first reference value corresponding to each of the degradation information may be changed. A detailed description thereof will be given with reference to FIGS. 11, 15, and 21. If the flash conversion layer 320 generates the command for adjusting the core of the adjacent sub-block, in a step S1040, the read or program operation on the selected sub-block may be performed. In addition, the read or program operation on the selected sub-block may be performed in a state in which the first reference value that is the deterioration information of the adjacent sub-block is increased. A description thereof will be given in detail with reference to FIGS. 11 and 15.

In the step S1030, if the deterioration information of the adjacent sub-block is less than the first reference value, the storage controller 300 does not need to compensate for deterioration of the adjacent sub-block. In this case, the step S1040 may be omitted, and the read or program operation on the selected sub-block may be performed.

FIG. 11 is a flowchart for describing an example of a method of operating the storage device.

Referring to FIG. 1, FIG. 4, and FIG. 11, in the step S1010, the storage controller 300 may determine the selected sub-block to be read based on a read request received from the host device 110 of FIG. 1. In a step S1120-a, the RDM 321 may compare the read disturb count of the adjacent sub-block with the first reference value close to a read disturb deterioration threshold value.

If the read disturb count of the adjacent sub-block is determined to be greater than or equal to the first reference value, the RDM 321 may generate the first command RDD_CMD that lowers the pass voltage applied to the adjacent sub-block. In a step S1130-a, the flash interface 350 may provide the control logic 420 with the first command RDD_CMD that lowers the pass voltage applied to the adjacent sub-block.

The control logic 420 may provide the voltage control signal CTRL_VOL for lowering a voltage applied to each word line included in the adjacent sub-block to the voltage generator 450 based on the first command RDD_CMD provided from the flash interface 350. Accordingly, the voltage generator 450 may be generated by lowering the pass voltage applied to the word line of each memory cell included in the adjacent sub-block.

If a size of the pass voltage applied to the word line of each cell included in the adjacent sub-block is high, an internal structure of cells included in the adjacent sub-block may be deteriorated. However, as the size of the pass voltage applied to the word line of each cell included in the adjacent sub-block becomes smaller, the read disturb deterioration threshold value of the adjacent sub-block may be increased. If the read disturb deterioration threshold value increases, the first reference value close to the read disturb deterioration threshold value may also be increased. Accordingly, the storage controller 300 and the non-volatile memory device 220 may compensate for performance degradation of the storage device 120 of FIG. 1 by lowering the pass voltage applied to the adjacent sub-block.

In the step S1040, the storage controller 300 may omit a copyback process for the adjacent sub-block, and may immediately perform a read operation for the selected sub-block. If the read disturb count is less than the first reference value in the step S1120-a, the storage controller 300 may omit the step S1130-a, and may perform a read operation for the selected sub-block.

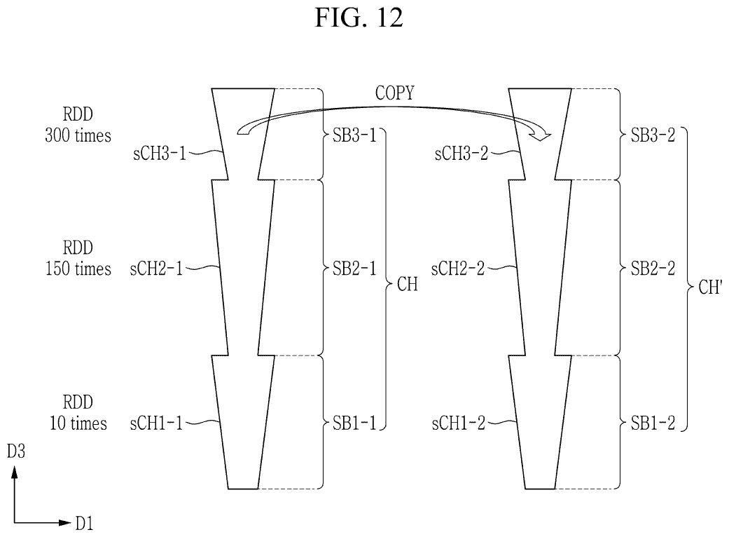

FIG. 12 is a view showing an example of the copyback process for the adjacent sub-block in which the read disturb count exceeds the deterioration threshold value.

For convenience of description, it is assumed that a second sub-block SB2-1 is a selected sub-block to be read and a first sub-block SB1-1 and a third sub-block SB3-1 are adjacent sub-blocks adjacent to the selected sub-block.

Referring to FIG. 8 and FIG. 12, the first sub-block SB1-1 may include the memory cells connected to the first to fourth word lines WL1, WL2, WL3, and WL4, and the read disturb count of the first sub-block SB1-1 may be 10 times. The second sub-block SB2-1 may include the memory cells connected to the fifth to ninth word lines WL5, WL6, WL7, WL8, and WL9, and the read disturb count of the second sub-block SB2-1 may be 150 times. The third sub-block SB3-1 may include the memory cells connected to the tenth to twelfth word lines WL10, WL11, and WL12, and the read disturb count of the third sub-block SB3-1 may be 300 times.

The channel hole CH may include first to third sub-channel holes sCH1-1, sCH2-1, and sCH3-1 disposed along the third direction D3. Memory cells connected to a word line included in the first sub-block SB1, the second sub-block SB2, and the third sub-block SB3 may be formed in each of the first sub-channel hole sCH1-1, the second sub-channel hole sCH2-1, and the third sub-channel hole sCH3-1.

If the disturb deterioration threshold value of each of the first sub-block SB1-1, the second sub-block SB2-1, and the third sub-block SB3-1 is 300 times, the third sub-block SB3-1 may be read due to deterioration of the third sub-block SB3-1 even if the selected sub-block to be read is the second sub-block SB2-1. Accordingly, the copyback process may be performed on the third sub-block SB3-1.

The copyback process may be performed between the third sub-block SB3-1 and the third sub-block SB3-2 included in the channel hole CH′. For example, data stored in memory cells included in the third sub-block SB3-1 may be copied and stored corresponding to each memory cell included in the third sub-block SB3-2.

Similarly, if the read disturb count of each of the first sub-block SB1-1 and the second sub-block SB2-1 reaches the disturb deterioration threshold value, data stored in memory cells included in the first sub-block SB1-1 and the second sub-block SB2-1 may be stored in memory cells included in the first sub-block SB1-2 and the second sub-block SB2-2 included in the channel hole CH′.

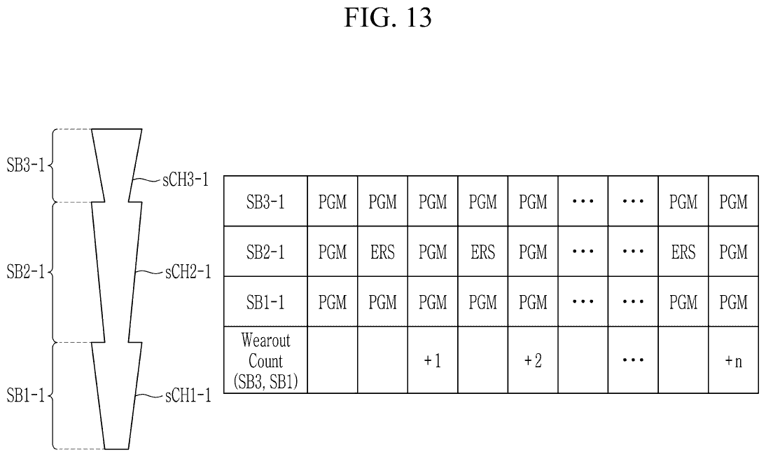

FIG. 13 is a view showing an example of the program wearout count gradually increasing in the adjacent sub-block.

For convenience of description, it is assumed that a second sub-block SB2-1 is a selected sub-block to be programmed and erased and a first sub-block SB1-1 and a third sub-block SB3-1 are adjacent sub-blocks adjacent to the selected sub-block.

Referring to FIG. 3, FIG. 8, and FIG. 13, it may be seen that a program state is maintained in the first sub-block SB1-1 and the third sub-block SB3-1 and program and erase states are repeated in the second sub-block SB2-1. A program operation may be performed in a unit of a page, and an erase operation may be performed in a unit of a block. Considering this, in order to change some of data stored in the block into new data, the erase operation for an existing block itself and the program operation for the new block may be sequentially performed. Accordingly, the program and erase states of the selected sub-block SB2-1 may be repeated in order to replace data stored in the selected sub-block SB2-1 with new data.

Based on the erase operation and the program operation for the second sub-block SB2-1, write interference and erase spike may occur in the first sub-block SB1-1 and the third sub-block SB3-1 that are the adjacent sub-blocks. Specifically, a state of a memory cell included in the first sub-block SB1-1 and the third sub-block SB3-1 adjacent to the second sub-block SB2-1 may be changed due to a change in a voltage or a current generated during an erase operation of the second sub-block SB2-1. In addition, an electric charge generated during a program operation process for the second sub-block SB2-1 may flow to memory cells included in the first sub-block SB1-1 and the third sub-block SB3-1 adjacent to the second sub-block SB2-1 so that a state of the memory cell is changed.

The program wearout count of each of the first sub-block SB1-1 and the third sub-block SB3-1 may be gradually increased due to the write interference and the erase spike occurring in the first sub-block SB1-1 and the third sub-block SB3-1. For example, if program and erase operations are repeatedly performed in the second sub-block SB2-1 so that the second sub-block SB2-1 reaches an erase state, the program wearout count of each of the first sub-block SB1-1 and the third sub-block SB3-1 may be increased by +1.

If the program wearout count of each of the first sub-block SB1-1 and the third sub-block SB3-1 reaches a program wearout threshold value, the program operation may no longer be performed on the first sub-block SB1-1 and the third sub-block SB3-1, and a copyback process may be performed on the first sub-block SB1-1 and the third sub-block SB3-1.

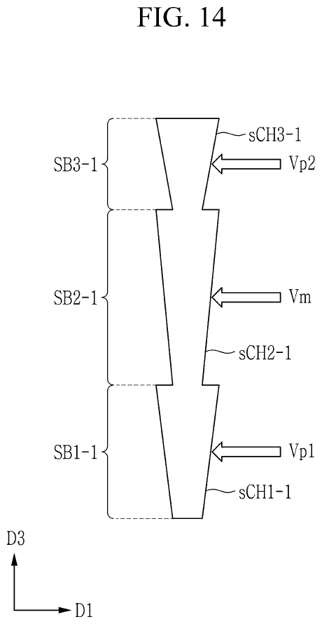

FIG. 14 is a view showing an example of a voltage applied to the memory cell included in each of the sub-blocks of FIGS. 11 to 13.

Referring to FIG. 14, a first pass voltage Vp1 may be applied to a memory cell included in the first sub-block SB1-1, an operation voltage Vm that is a read voltage, a program voltage, or an erase voltage may be applied to a memory cell included in the second sub-block SB2-1, and a third pass voltage Vp2 may be applied to a memory cell included in the third sub-block SB3-1.

Referring to FIGS. 11 to 13, the read disturb count of the third sub-block SB3-1 reaches the disturb deterioration threshold value, and the program wearout count of the third sub-block SB3-1 exceeds the program wearout threshold value. In this case, a copyback process for the third sub-block SB3-1 is required. In order to omit the copyback process, the second pass voltage Vp2 applied to the third sub-block SB3-1 may be lowered.

If the second pass voltage Vp2 decreases, the disturb deterioration threshold value and the program wearout threshold value corresponding to the third sub-block SB3-1 may increase. Accordingly, if the second pass voltage Vp2 applied to the third sub-block SB3-1 becomes lower, the copyback process for the third sub-block SB3-1 may be delayed. The storage controller 300 of FIG. 3 may adjust the second pass voltage Vp2 applied to the sub-block SB3-1, so that performance degradation of the storage device 120 of FIG. 1 is compensated.

A time point at which the second pass voltage Vp2 applied to the third sub-block SB3-1 is lowered may be based on a time when the read disturb count reaches the first reference value close to the disturb deterioration threshold value. A time point at which the second pass voltage Vp2 applied to the third sub-block SB3-1 is lowered may be based on a time when the program wearout count reaches a second reference value close to the program wearout threshold value.

A time point at which the second pass voltage Vp2 applied to the third sub-block SB3-1 is lowered may be based on a time when a value obtained by summing the read disturb count and the program wearout count reaches a third reference value considering both the disturb deterioration threshold value and the program wearout threshold value. In this case, a method of summing the read disturb count and the program wearout count and a method of calculating the third reference value are not limited.

FIG. 15 is a flowchart for describing an example of a method of operating the storage device.

Referring to FIG. 3, FIG. 10, and FIG. 15, in the step S1010, the storage controller 300 may determine a selected sub-block to be read based on a read request received from the host device 110 of FIG. 1. In a step S1520-b, the PEM 322 may compare the program/erase cycle count of the adjacent sub-block adjacent to the selected sub-block with the first reference value close to a program/erase cycle threshold value. In this case, the selected sub-block and the adjacent sub-block that are read targets may be included in the same hole block.

If the program/erase cycle count of the adjacent sub-block is determined to be greater than or equal to the first reference value, the PEM 322 may generate the second command P/E_CMD increasing the pass voltage applied to the adjacent sub-block. In a step S1530-b, the flash interface 350 may provide the control logic 420 with the second command P/E_CMD increasing the pass voltage applied to the adjacent sub-block.

Based on the second command P/E_CMD provided from the flash interface 350, the control logic 420 may provide the voltage generator 450 with the voltage control signal CTRL_VOL increasing a voltage applied to each word line included in the adjacent sub-block. Accordingly, the voltage generator 450 may be generated by increasing the pass voltage applied to the word line of each memory cell included in the adjacent sub-block.

As a size of the pass voltage applied to the word line of each cell included in the adjacent sub-block becomes larger, the program/erase cycle threshold value of the adjacent sub-block may be increased. If the program/erase cycle threshold value increases, the first reference value close to the program/erase cycle threshold value may also increase. Accordingly, the storage controller 300 and the non-volatile memory device 220 may compensate for performance degradation of the storage device 120 of FIG. 1 by increasing the pass voltage applied to the adjacent sub-block.

In some implementations, after the storage controller 300 determines the selected sub-block, the PEM 322 may compare the program/erase cycle count of the plurality of sub-blocks included in the hole block with the first reference value close to the program/erase cycle threshold. If there are a plurality of sub-blocks corresponding to the program/erase cycle count equal to or greater than the first reference value, the PEM 322 may generate the second command P/E_CMD for increasing the pass voltage applied to the plurality of sub-blocks. In this case, read disturb counts of the plurality of sub-blocks may be considered.

In a case of a sub-block with a high read disturb count among the plurality of sub-blocks, additional deterioration may occur due to an increase in the pass voltage. Accordingly, the PEM 322 may generate the second command P/E_CMD that preferentially increases the pass voltage in a sub-block with a low read disturb count among the plurality of sub-blocks. Conversely, in a case of a sub-block with a high program/erase cycle count among the plurality of sub-blocks, additional deterioration may occur due to a drop in the pass voltage. Accordingly, the RDM 321 may generate the first command RDD_CMD that preferentially lowers the pass voltage of a sub-block with a low program/erase cycle count among the plurality of sub-blocks.

In a step S1050, the storage controller 300 may omit a copyback process for the adjacent sub-block, and may immediately perform a read operation for the selected sub-block. If the program/erase cycle count is less than the first reference value in the step S1520-b, the storage controller 300 may omit the step S1530-b, and may perform a read operation for the selected sub-block.

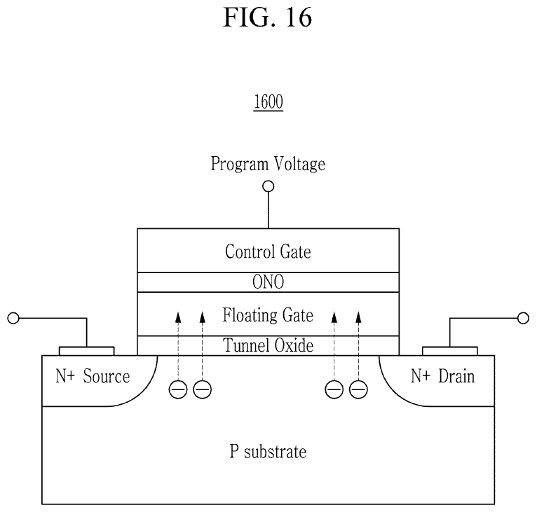

FIG. 16 is a view showing an example of a program process in which an electron is filled in a floating gate included in a memory cell.

For convenience of description, it is assumed that the memory cell 1600 of FIG. 16 is a NAND flash memory cell. If a program voltage (Program Voltage) is input to a control gate (Control Gate) during the program process of storing data in the memory cell 1600, electrons included in a substrate (P substrate) may flow into a floating gate (Floating Gate). The floating gate may be surrounded by a non-conductor with very high insulation, so that the electrons introduced into the floating gate may not escape even if the program voltage is not applied to the control gate.

The NAND flash memory cell may adjust a threshold voltage value of the memory cell 1600 based on an amount of the electron introduced into the floating gate (Floating Gate). As the number of electrons introduced into the floating gate (Floating Gate) increases, the threshold voltage of the memory cell 1600 may be increased.

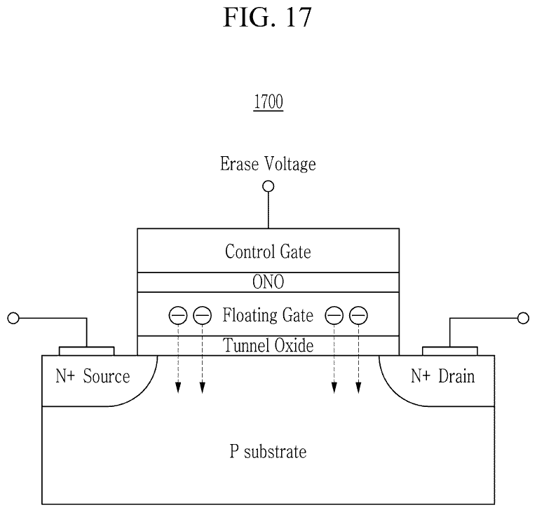

FIG. 17 is a view showing an example of an erase process in which an electron falls into the floating gate within a non-volatile memory device.

If an erase voltage (Erase Voltage) is input to a control gate (Control Gate) during the erase process of removing data stored in a memory cell 1700, electrons captured in a floating gate (Floating Gate) may escape to a substrate (P substrate). A method of inputting the erase voltage (Erase Voltage) to the control gate (Control Gate) may be a method of grounding the control gate (Control Gate) and applying a strong positive voltage to the substrate (P substrate). As the number of electrons escaping from the floating gate (Floating Gate) increases, a threshold voltage of the memory cell 1700 may be lowered

Referring to FIG. 8, FIG. 16, and FIG. 17, if the programming process and the erase process are repeated, a process in which the electrons flow into the floating gate (Floating Gate) from the substrate (P substrate) and the electron escapes from the floating gate (Floating Gate) to the substrate (P substrate) may be repeated. During the repetitive program and erase processes, the electrons introduced into the floating gate (Floating Gate) may not escape to the substrate (P substrate), and may remain in the floating gate (Floating Gate).

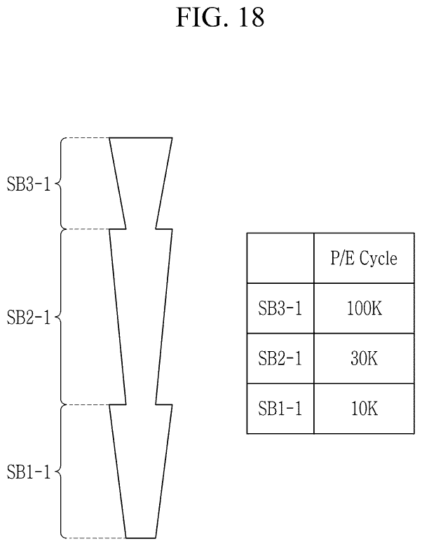

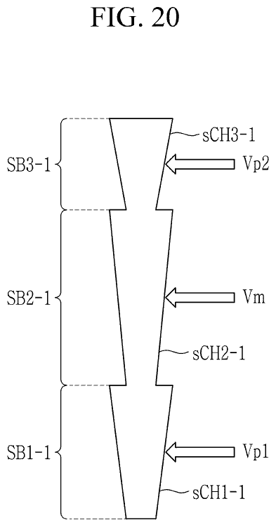

Accordingly, more electrons may be captured in the memory cell 1600 in a program state by the floating gate (Floating Gate), and the threshold voltage of the memory cell 1600 may be increased. If threshold voltages of a plurality of memory cells 1600 included in the adjacent sub-block increase, a current flowing in each of the plurality of memory cells 1600 may decrease, so that the current may not flow to the memory cell of the selected block that is a read target. A description thereof will be given in detail with reference to FIGS. 18 and 20.

FIG. 18 is a view showing an example of the program/erase cycle count corresponding to each sub-block.

Referring to FIG. 18, the program/erase cycle count of the first sub-block SB1-1 is 100 k, the program/erase cycle count of the second sub-block SB2-1 is 30 k, and the program/erase cycle count of the third sub-block SB3-1 is 10 k. If a program/erase count threshold value of each of the first sub-block SB1-1, the second sub-block SB2-1, and the third sub-block SB3-1 is 100 k, program and erase processes may no longer be performed.

A copyback process may be performed on the third sub-block SB3-1 in which the program/erase count reaches the threshold value among the plurality of sub-blocks SB1-1, SB2-1, and SB3-1. A program/erase operation process for the plurality of sub-blocks SB1-1 and SB2-1 may be stopped due to the copyback process for the third sub-block SB3-1, and performance of the storage device 120 of FIG. 1 may be degraded.

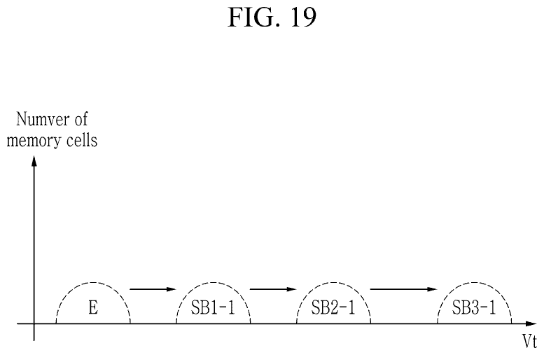

FIG. 19 is a view for describing an example of a threshold voltage for the sub-block of FIG. 18.

Referring to FIGS. 16 to 19, a threshold voltage Vt of each of the sub-block in an initial state, the first sub-block SB1-1, the second sub-block SB2-1, and the third sub-block SB3-1 may be increased based on an increase amount in a program/erase cycle count for each of the sub-blocks.

Because the program/erase cycle count (10 k) of the first sub-block SB1-1 is higher than the program/erase cycle count (0 k) of the initial state sub-block E, an amount of the electron captured at the floating gate (Floating Gate) of the first sub-block SB1-1 may be greater than an amount of the electron captured at the floating gate (Floating Gate) of the initial state sub-block E. Accordingly, the threshold voltage Vt of the memory cell included in the first sub-block SB1-1 may be higher than the threshold voltage Vt of the memory cell included in the initial state sub-block E.

Because the program/erase cycle count (30 k) of the second sub-block SB2-1 is higher than the program/erase cycle count (10 k) of the first sub-block SB1-1, an amount of the electron captured at the floating gate (Floating Gate) of the second sub-block SB2-1 may be greater than an amount of the electron captured at the floating gate (Floating Gate) of the first sub-block SB1-1. Accordingly, the threshold voltage Vt of the memory cell included in the second sub-block SB2-1 may be higher than the threshold voltage Vt of the memory cell included in the first sub-block SB1-1.

Because the program/erase cycle count (100 k) of the third sub-block SB3-1 is higher than the program/erase cycle count (30 k) of the second sub-block SB2-1, an amount of the electron captured at the floating gate (Floating Gate) of the third sub-block SB3-1 may be greater than an amount of the electron captured at the floating gate (Floating Gate) of the second sub-block SB2-1. Accordingly, the threshold voltage Vt of the memory cell included in the third sub-block SB3-1 may be higher than the threshold voltage Vt of the memory cell included in the second sub-block SB2-1.

FIG. 20 is a view showing an example of a voltage applied to the memory cell included in each sub-block of FIG. 18.

Referring to FIG. 20, a first pass voltage Vp1 may be applied to the memory cell included in the first sub-block SB1-1, an operation voltage Vm that is a read voltage, a program voltage, or an erase voltage may be applied to the memory cell included in the second sub-block SB2-1, and a third pass voltage Vp2 may be applied to the memory cell included in the third sub-block SB3-1.

Referring to FIGS. 16 to 19, if the program/erase cycle count of the third sub-block SB3-1 reaches a threshold value, a threshold voltage of the memory cell included in the third sub-block SB3-1 may increase. In addition, if the threshold voltage of the memory cell increases and the memory cell receives the same pass voltage as the previous pass voltage, a current flowing in the memory cell may decrease, so that the current may not flow to the memory cell of the selected sub-block that is a read target. Accordingly, the storage controller 300 of FIG. 3 may increase the second pass voltage Vp2 applied to the third sub-block SB3-1.

If the second pass voltage Vp2 increases, a size of a current flowing in the memory cell included in the third sub-block SB3-1 may increase, and the current may flow to the memory cell of the selected sub-block that is the read target. The storage controller 300 may compensate for performance degradation of the storage device 120 of FIG. 1 by adjusting the second pass voltage Vp2 applied to the sub-block SB3-1.

A time point at which the second pass voltage Vp2 applied to the third sub-block SB3-1 is increased may be based on a time when the program/erase cycle count reaches the first reference value close to the threshold value.

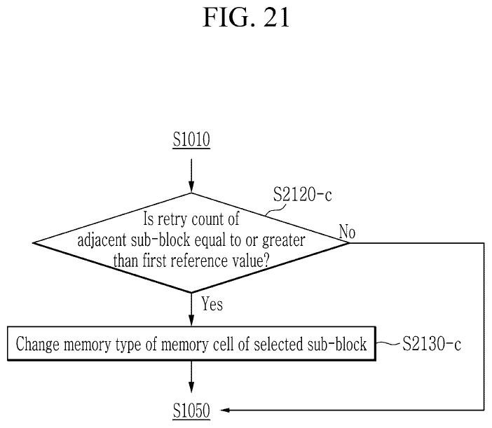

FIG. 21 is a flowchart for describing an example of a method of operating the storage device.

Referring to FIG. 1, FIG. 4, and FIG. 21, in the step S1010, the storage controller 300 of FIG. 3 may determine a selected sub-block to be programmed based on a program request received from the host device 110 of FIG. 1. In a step S2120-c, the RTM 323 may compare the retry count of the adjacent sub-block with a first reference value close to a threshold value of the retry count. In this case, the retry count may mean the number of times the storage system 100 of FIG. 1 takes a specific action to process an error occurring in the adjacent sub-block during the read or program process. The error occurring in the adjacent sub-block may include a defect in the memory cell included in the sub-block, integrity of data stored in the memory, environmental conditions such as noise, temperature, and humidity occurring in a surrounding environment, or the like.

If the retry count of the adjacent sub-block is determined to be greater than or equal to the first reference value, the RTM 323 may generate the third command RETRY_CMD for changing a memory cell type for the plurality of sub-blocks included in the hole block. In this case, the plurality of sub-blocks included in the hole block may include the selected sub-block that is the program target and the adjacent sub-block adjacent to the selected sub-block.

In some implementations, the RTM 323 may compare the retry count of the selected sub-block with the first reference value close to the threshold value of the retry count. If the retry count of the selected sub-block is determined to be greater than or equal to the first reference value, the RTM 323 may generate the third command RETRY_CMD for changing the memory cell type for the plurality of sub-blocks included in the hole block.

For example, if the first sub-block, the second sub-block, and the third sub-block are sequentially stacked within the hole block and the retry count of the second sub-block that is the selected sub-block is determined to be greater than or equal to the first reference value, the RTM 323 may generate the third command RETRY_CMD changing memory cell types for the first to third sub-blocks. An error possibility occurring in the selected sub-block in which the retry count exceeds the first reference value may also affect the first sub-block and third sub-block sharing the string with the selected sub-block. Accordingly, the RTM 323 may generate the third command RETRY_CMD that changes the memory cell types for the plurality of sub-blocks included in the hole block to the SLC type.

In some implementations, the RTM 323 may compare the retry count of one sub-block among the plurality of sub-blocks included in the hole block with the first reference value close to the threshold value of the retry count. If the retry count of the sub-block included in the hole block is determined to be greater than or equal to the first reference value, the RTM 323 may generate the third command RETRY_CMD for changing memory cell types for all sub-blocks included in the hole block.

In a step S2130-c, the flash interface 350 may provide the control logic 420 with the third command RETRY_CMD for changing a memory type of the memory cell included in the selected sub-block. The control logic 420 may change the memory cell type of the selected sub-block that is a program target based on the third command RETRY_CMD provided from the flash interface 350. For example, if the RTM 323 generates the third command RETRY_CMD that changes the memory cell type included in the selected sub-block to the SLC type, the control logic 420 may change the type of the memory cell included in the selected sub-block to the SLC type.

In some implementations, the flash interface 350 may provide the control logic 420 with the third command RETRY_CMD for changing the memory type of the memory cell included in the hole block. The control logic 420 may change the memory cell type of all sub-blocks included in the hole block based on the third command RETRY_CMD provided from the flash interface 350. For example, if the RTM 323 generates the third command RETRY_CMD that changes the memory cell type of all sub-blocks included in the hole block to the SLC type, the control logic 420 may change the memory cell type included in all sub-blocks included in the hole block to the SLC type.

If the program operation is performed using the SLC type, each memory cell included in the selected sub-block may store one bit so that accuracy of data is increased. Additionally, each cell may store one bit, so that the program operation is quickly performed.

In the step S1050, the program operation may be performed on the selected sub-block using the SLC type. In addition, if the program operation is changed for another selected sub-block included within the hole block (WH) including the selected sub-block, the program operation may be performed using the SLC type for the changed selected sub-block.

If the retry count is less than the first reference value in step S2120-c, the storage controller 300 may omit step S2130-c, and may perform the program operation for the selected sub-block. In this case, the program operation may be performed in the memory cell included in the selected sub-block to be programmed using a multi-level cell (MLC) type, a triple-level cell (TLC) type, a quad-level cell (QLC) type, and the like.

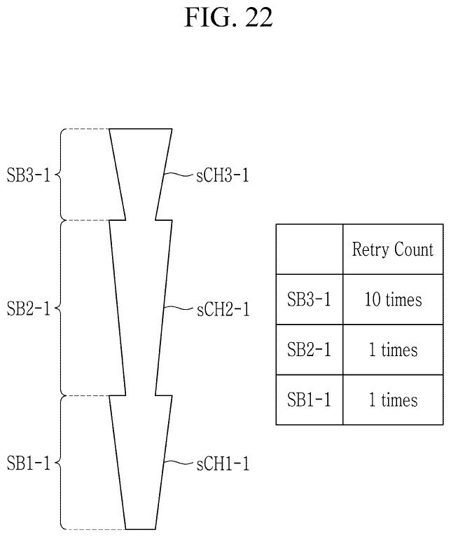

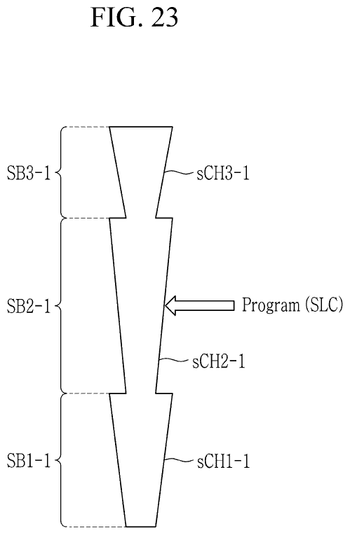

FIG. 22 is a view showing an example of the retry count corresponding to each sub-block.

For convenience of description, it is assumed that the second sub-block SB2-1 is a selected sub-block to be programmed and the first sub-block SB1-1 and the third sub-block SB3-1 are adjacent sub-blocks adjacent to the selected sub-block.

Referring to FIG. 22, the retry count of the first sub-block SB1-1 is 10 times, the retry count of the second sub-block SB2-1 is 1 time, and the retry count of the third sub-block SB3-1 is 1 time. If a threshold value of the retry count of each of the first sub-block SB1-1, the second sub-block SB2-1, and the third sub-block SB3-1 is 10 times, the retry count of the third sub-block SB3-1 may already reach the threshold value.

A copyback process may be performed on the third sub-block SB3-1 in which the retry count reaches the threshold value among the plurality of sub-blocks SB1-1, SB2-1, and SB3-1. A program operation process for the second sub-block SB2-1 may be stopped due to the copyback process for the third sub-block SB3-1. Accordingly, performance of the storage device 120 of FIG. 1 may be degraded.

FIG. 23 is a view showing an example of a voltage applied to the memory cell included in each sub-block of FIG. 22.

Referring to FIG. 22 and FIG. 23, the retry count of the third sub-block SB3 may reach the threshold value, so that an error may occur in a program operation of the second sub-block SB2 adjacent to the third sub-block SB3. Accordingly, data may be stored in the SLC type in the memory cell included in the second sub-block SB2. If the program operation is performed on the second sub-block SB2 in the SLC type, each of memory cells included in the second sub-block SB2 only needs to have two states with one bit, so that a possibility of a data error may be reduced.

A time point for changing the type of the memory cell included in the second sub-block SB2-1 may be based on a time when the retry count of the third sub-block SB3-1 reaches the first reference value close to the threshold.

In FIGS. 1 to 23, the read disturb count, the program/erase cycle count, and the retry count of the adjacent sub-block may simultaneously reach reference values close to their respective thresholds. In this case, the storage controller 300 may set a priority based on an operation policy of the memory, and may adjust cores of the adjacent sub-block and the selected sub-block.

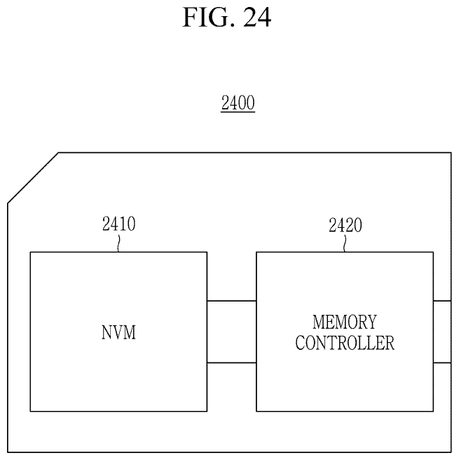

FIG. 24 is a block diagram showing an example of a data storage device including a non-volatile memory device. Referring to FIG. 24, the data storage device 2400 may include a non-volatile memory device 2410 and a memory controller 2420.

The memory controller 2420 may control a program/read/erase operation of a non-volatile memory device 2410 in response to a request from the outside.

As described with reference to FIGS. 1 to 23, the memory controller 2420 may monitor the disturb situation based on the sub-block within the non-volatile memory device 2410, and the non-volatile memory device 2410 may generate the disturb information (i.e., the read disturb count, the program wearout count, the program/erase cycle count, and the retry count) of the sub-block according to the monitor result, and may adjust the operation condition according to the disturb information.

Through the operation described with reference to FIGS. 1 to 23, the non-volatile memory device 2410 may improve a reliability problem caused by a disturb phenomenon, and the data storage device 2400 may improve performance by reducing the number of copyback operations.

The data storage device 2400 may constitute a memory card device, an SSD device, a multimedia card device, an SD device, a memory stick device, a hard disk drive device, a hybrid drive device, or a general-purpose serial bus flash device. For example, the data storage device 2400 may constitute a card for using a user device such as a digital camera, a personal computer, or the like.

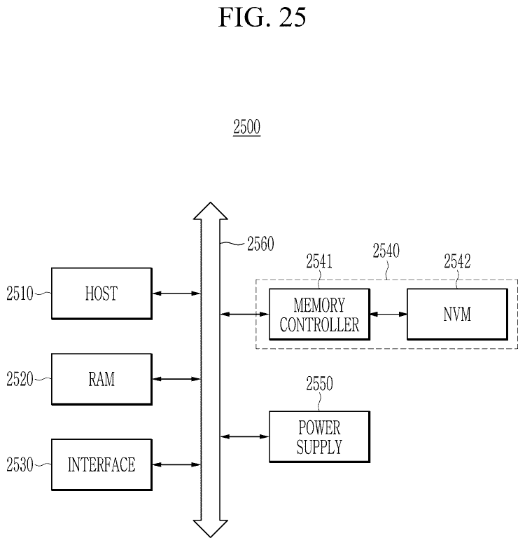

FIG. 25 is a block diagram showing an example of a computer system including a non-volatile memory device.

Referring to FIG. 25, the computer system 2500 may include a processor 2510, a RAM 2520, an interface device 2530, a memory system 2540, a power supply device 2550, and a bus 2560.

The processor 2510, the RAM 2520, the interface device 2530, the memory system 2540, and the power supply device 2550 may be coupled to each other through the bus 2560. The bus 2560 corresponds to a path through which data are moved.

The processor 2510 may include at least one of a microprocessor, a digital signal processor, a microcontroller, and logical elements capable of performing functions similar to functions of the microprocessor, the digital signal processor, and the microcontroller.

The RAM 2520 may be used as a working memory for improving performance of the processor 2510. The interface device 2530 may perform a function of transmitting data to a communication network or receiving data from the communication network.

The interface device 2530 may be in a wired or wireless form. For example, the interface device 2530 may include an antenna, a wired/wireless transceiver, or the like.

The memory system 2540 may store data and/or a command. The memory system 2540 may include a memory controller 2541 and a non-volatile memory device 2542.

The memory controller 2541 may control a program/read/erase operation of the non-volatile memory device 2542. The non-volatile memory device 2542 may include a plurality of non-volatile memory chips.

As described with reference to FIGS. 1 to 23, the memory controller 2541 may monitor the disturb situation based on the sub-block within the non-volatile memory device 2542, and the non-volatile memory device 2542 may generate the disturb information of the sub-block according to the monitor result, and may adjust the operation condition according to the disturb information. Through the operation described with reference to FIGS. 1 to 23, the non-volatile memory device 2542 may improve a reliability problem caused by a disturb phenomenon, and the memory system 2540 may improve performance by reducing the number of read reclaim operations.

The power supply device 2550 may supply operating power of the processor 2510, the RAM 2520, the interface device 2530, and the memory system 2540.

The computer system 2500 may be applied to a personal digital assistant (PDA), a portable computer, a web tablet, a wireless phone, a mobile phone, a digital music player, a memory card, or any electronic product capable of transmitting and/or receiving information in a wireless environment.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described in connection with the disclosed implementations, it is to be understood that the disclosure is not limited to the disclosed implementations, but, on the contrary, is intended to cover various modifications and equivalent arrangements included within the spirit and scope of the appended claims.

What is claimed is:

1. A storage controller comprising:
a host interface configured to receive a read request or a program request from a host device;
a flash conversion layer configured to
collect deterioration information on a non-volatile memory device and log the deterioration information in a unit of a sub-block,
select a first sub-block and a second sub-block adjacent to the first sub-block based on the read request or the program request, and
generate a command that adjusts a core of the second sub-block based on the deterioration information; and
a flash interface configured to transfer the command to the non-volatile memory device.

2. The storage controller of claim 1, wherein the flash conversion layer comprises a sub-block read disturb checking circuit configured to generate a first command that adjusts a pass voltage applied to the second sub-block based on a read disturb count, the first command included in the command, and the read disturb count included in the deterioration information.

3. The storage controller of claim 2, wherein the first command is configured to lower the pass voltage applied to the second sub-block based on a number of read disturbs generated in the second sub-block being greater than or equal to a first reference value, and the number of read disturbs generated in the second sub-block is determined based on the read disturb count.

4. The storage controller of claim 1, wherein the flash conversion layer comprises a sub-block program/erase cycle checking circuit configured to generate a second command that adjusts a pass voltage applied to the second sub-block based on a program/erase cycle count, the second command included in the command, and the program/erase cycle count included in the deterioration information.

5. The storage controller of claim 4, wherein the second command is configured to increase the pass voltage applied to the second sub-block based on a number of program/erase cycles occurring in the second sub-block being greater than or equal to a first reference value, and the number of program/erase cycles occurring in the second sub-block is determined based on the program/erase cycle count.

6. The storage controller of claim 1, wherein the flash conversion layer comprises a sub-block retry checking circuit configured to generate a third command that adjusts a pass voltage applied to the second sub-block based on a retry count, the third command included in the command, and the retry count included in the deterioration information.

7. The storage controller of claim 6, wherein the third command is configured to change a type of a memory cell included in the first sub-block based on a number of retries occurring in the second sub-block being greater than or equal to a first reference value, and the number of retries occurring in the second sub-block is determined based on the retry count.

8. The storage controller of claim 7, wherein the third command includes a command that changes the type of the memory cell included in the first sub-block to a single level cell (SLC) type.

9. The storage controller of claim 6, wherein the third command is configured to change a type of a memory cell of all sub-blocks within a hole block included in the first sub-block to a single level cell (SLC) type based on a number of retries occurring in the second sub-block being greater than or equal to a first reference value, and the number of retries occurring in the second sub-block is determined based on the retry count.

10. A storage device comprising:
a storage controller configured to
select a first sub-block and a second sub-block adjacent to the first sub-block among a plurality of sub-blocks based on a read request or a program request from a host device, and
generate a command that adjusts a core of the second sub-block based on a disturb generated in the second sub-block exceeding a first reference value; and
a non-volatile memory device that includes the plurality of sub-blocks, the non-volatile memory device configured to adjust a size of a pass voltage applied to a word line included in the second sub-block based on the command and an address of the second sub-block.

11. The storage device of claim 10, wherein the non-volatile memory device comprises a voltage generator configured to generate the pass voltage.

12. The storage device of claim 11, wherein the non-volatile memory device includes a control logic configured to provide the voltage generator with a voltage control signal, the voltage control signal changing the pass voltage applied to the word line included in the second sub-block based on the command and the address of the second sub-block.

13. The storage device of claim 12, wherein
the storage controller is configured to generate a first command that lower the pass voltage applied to the second sub-block based on a read disturb occurring in the second sub-block exceeding a first reference value,
the control logic is configured to provide the voltage generator with the voltage control signal that lowers the pass voltage applied to the second sub-block based on the first command, and
the voltage generator is configured to generate the pass voltage applied to the word line of each memory cell included in the second sub-block based on the voltage control signal.

14. The storage device of claim 12, wherein
the storage controller is configured to generate a second command that increases the pass voltage applied to the second sub-block based on a number of program/erase cycles occurring in the second sub-block exceeding a first reference value,
the control logic is configured to provide the voltage generator with the voltage control signal that increases the pass voltage applied to the second sub-block based on the second command, and
the voltage generator is configured to generate the pass voltage applied to the word line of each memory cell included in the second sub-block based on the voltage control signal.

15. The storage device of claim 11, wherein the storage controller is configured to generate a third command that changes a type of a memory cell included in the first sub-block based on a number of retries occurring in the second sub-block.

16. The storage device of claim 15, wherein based on the number of retries occurring in the second sub-block exceeding a first reference value, the storage controller is configured to generate the third command that changes the type of the memory cell included in the first sub-block to a single level cell (SLC) type.

17. A method of operating a storage device, comprising:
selecting a first sub-block configured to be a target of a read operation or a program operation among a plurality of sub-blocks, the plurality of sub-blocks distinguished from each other through a plurality of word lines;
determining whether deterioration information of a second sub-block adjacent to the first sub-block is greater than or equal to a first reference value; and
adjusting a core of the second sub-block based on the deterioration information of the second sub-block being greater than or equal to the first reference value.

18. The method of claim 17, wherein the first sub-block is configured to be the target of the read operation, determining whether the deterioration information of the second sub-block is greater than or equal to the first reference value comprises determining whether a read disturb occurring in the second sub-block is greater than or equal to the first reference value, and adjusting the core of the second sub-block based on the deterioration information of the second sub-block being greater than or equal to the first reference value comprises generating a first command that lowers a pass voltage applied to the second sub-block based on the read disturb occurring in the second sub-block being greater than or equal to the first reference value.

19. The method of claim 17, wherein the first sub-block is configured to be the target of the read operation, determining whether the deterioration information of the second sub-block is greater than or equal to the first reference value comprises determining whether a number of program/erase cycles occurring in the second sub-block is greater than or equal to the first reference value, and adjusting the core of the second sub-block based on the deterioration information of the second sub-block being greater than or equal to the first reference value comprises generating a second command that increases a pass voltage applied to the second sub-block based on the number of program/erase cycles occurring in the second sub-block being greater than or equal to the first reference value.

20. The method of claim 17, wherein the first sub-block is configured to be the target of the program operation, determining whether the deterioration information of the second sub-block is greater than or equal to the first reference value comprises determining whether a number of retries occurring in the second sub-block is greater than or equal to the first reference value, and adjusting the core of the second sub-block based on the deterioration information of the second sub-block being greater than or equal to the first reference value comprises generating a third command that changes a type of a memory cell included in the first sub-block to a single level cell (SLC) type based on the number of retries occurring in the second sub-block being greater than or equal to the first reference value.
